(19) United States
(12) Patent Application Publication
(10) Pub. No.: US 2023/0049448 A1
(43) Pub. Date: Feb. 16, 2023

(54) ZERO-POINT CALIBRATION METHOD, DEVICE, AND APPARATUS, ELECTRONIC DEVICE, AND COMPUTER-READABLE STORAGE MEDIUM

(71) Applicant: Shenzhen Reolink Technology Co., Ltd., Shenzhen (CN)

(72) Inventors: Sheng YONG, Shenzhen (CN); Xiaoyu LIU, Shenzhen (CN); Rui ZHOU, Shenzhen (CN); Yulong QUE, Shenzhen (CN)

(21) Appl. No.: 17/567,834

(22) Filed: Jan. 3, 2022

(30) Foreign Application Priority Data
Aug. 16, 2021 (CN) 202110935274.X

(51) Int. Cl. G01P 21/00; G01P 1/00; G01P 15/18

(52) U.S. Cl. CPC G01P 21/00; G01P 1/00; G01P 15/18

(57) ABSTRACT

This application discloses a vector sensor zero-point calibration method, device, and, apparatus, an electronic device, and a non-volatile computer-readable storage medium. The calibration method includes: acquiring reference data during two measurements of a reference vector performed by a vector sensor; acquiring a zero-point offset M₀ of the vector sensor according to the reference data; acquiring original data Rₖ of any vector measured by the vector sensor; and acquiring valid data Vₖ according to the zero-point offset M₀ and the original data Rₖ. With the calibration method in this application, the valid data Vₖ is obtained after a zero-point error of the original data Rₖ is eliminated, which is more closely approximated to an actual value of a to-be-measured vector.

### CROSS-REFERENCE TO RELATED APPLICATIONS

The present application claims priority from the Chinese Invention Patent Application No. 202110935274.X filed Aug. 16, 2021, and the disclosure of which is incorporated herein by reference in its entirety.

### FIELD OF THE INVENTION

This application relates to the field of sensors, and more specifically, to a vector sensor zero-point calibration method, device, and apparatus, an electronic device, and a non-volatile computer-readable storage medium.

### BACKGROUND OF THE INVENTION

A vector sensor can provide a direction and a size of a to-be-measured physical quantity. For example, a three-axis magnetoresistive sensor capable of measuring the direction of the earth magnetic field is used to manufacture a compass to achieve azimuth measurement. For another example, a three-axis acceleration sensor capable of measuring the gravity acceleration of the earth provides an angle of inclination relative to a horizontal plane. When the to-be-measured physical quantity is zero, data output of a sensor is often not zero, that is, a zero-point error exists. Therefore, how to reduce the zero-point error becomes a problem to be urgently resolved by those skilled in the art.

### SUMMARY OF THE INVENTION

Implementations of this application provide a zero-point calibration method, device, and apparatus for a vector sensor, an electronic device, and a non-volatile computer-readable storage medium.

The calibration method in the implementations of this application includes: acquiring reference data during two measurements of a reference vector performed by a vector sensor; acquiring a zero-point offset M₀ of the vector sensor according to the reference data; acquiring original data Rₖ of any vector measured by the vector sensor; and acquiring valid data Vₖ according to the zero-point offset M₀ and the original data Rₖ.

The zero-point calibration device in the implementations of this application includes one or more processors, a memory, and one or more programs stored in the memory and executable by the one or more processors, where the processors are configured to: acquire reference data during two measurements of a reference vector performed by a vector sensor; acquire a zero-point offset M₀ of the vector sensor according to the reference data; acquire original data Rₖ of any vector measured by the vector sensor; and acquire valid data Vₖ according to the zero-point offset M₀ and the original data Rₖ.

A distance measurement apparatus in the implementations of this application includes an acquisition module, a measurement module, and a calculation module. The acquisition module is configured to acquire reference data during two measurements of a reference vector performed by a vector sensor. The measurement module is configured to acquire a zero-point offset M₀ of the vector sensor according to the reference data. The calculation module is configured to acquire valid data Vₖ according to the zero-point offset M₀ and the original data Rₖ.

The electronic device in the implementations of this application includes a vector sensor and a zero-point calibration device and/or a zero-point calibration apparatus. The vector sensor is configured to measure a vector. The zero-point calibration device includes one or more processors, a memory, and one or more programs stored in the memory and executable by the one or more processors, where the processors are configured to: acquire reference data during two measurements of a reference vector performed by a vector sensor; acquire a zero-point offset M₀ of the vector sensor according to the reference data; acquire original data Rₖ of any vector measured by the vector sensor; and acquire valid data Vₖ according to the zero-point offset M₀ and the original data Rₖ. The distance measurement apparatus includes an acquisition module, a measurement module, and a calculation module. The acquisition module is configured to acquire reference data during two measurements of a reference vector performed by a vector sensor. The measurement module is configured to acquire a zero-point offset M₀ of the vector sensor according to the reference data. The calculation module is configured to acquire valid data Vₖ according to the zero-point offset M₀ and the original data Rₖ.

The non-volatile computer-readable storage medium in the implementations of this application includes a computer program which, when executed by one or more processors, causes the one or more processors to perform the following calibration method: acquiring reference data during two measurements of a reference vector performed by a vector sensor; acquiring a zero-point offset M₀ of the vector sensor according to the reference data; acquiring original data Rₖ of any vector measured by the vector sensor; and acquiring valid data Vₖ according to the zero-point offset M₀ and the original data Rₖ.

According to the zero-point calibration method, device, and apparatus for a vector sensor, the electronic device, and the non-volatile computer-readable storage medium in the implementations of this application, the zero-point offset M₀ of the vector sensor can be acquired according to the reference data during the two measurements of the reference vector, and the valid data Vₖ is acquired according to the original data Rₖ acquired by the vector sensor and the zero-point offset M₀. The valid data Vₖ is vector data obtained after a zero-point error of the original data Rₖ is eliminated, which is more closely approximated to an actual value of a to-be-measured vector.

Additional aspects and advantages of the implementations of this application are provided in the following description.

### BRIEF DESCRIPTION OF THE DRAWINGS

The foregoing and/or additional aspects and advantages of this application will become apparent and comprehensible from the following descriptions of the embodiments with reference to the accompanying drawings, where:

FIG. 1 is a schematic flowchart of a zero-point calibration method for a vector sensor according to some implementations of this application.

FIG. 2 is a schematic structural diagram of an electronic device according to some implementations of this application.

FIG. 3 is a schematic structural diagram of a zero-point calibration apparatus according to some implementations of this application.

FIG. 4 is a schematic diagram of a scenario in which a vector sensor acquires original data Rₖ and valid data Vₖ according to some implementations of this application.

FIG. 5 is a schematic diagram of a scenario of different postures of the vector sensor according to some implementations of this application.

FIG. 6 is a schematic diagram of a scenario in which the vector sensor acquires a zero-point offset M₀ according to some implementations of this application.

FIG. 7 is a schematic flowchart of a calibration method according to some implementations of this application.

FIG. 8 is a schematic flowchart of a calibration method according to some implementations of this application.

FIG. 9 is a schematic diagram of a connection state between a computer-readable storage medium and a processor according to some implementations of this application.

### DETAILED DESCRIPTION

The following describes implementations of this application in detail. Examples of the implementations are shown in the accompanying drawings, and same or similar reference signs in all the accompanying drawings indicate same or similar components or components having same or similar functions. The implementations that are described with reference to the accompanying drawings are exemplary, and are only used to explain implementations of this application and cannot be construed as a limitation to implementations of this application.

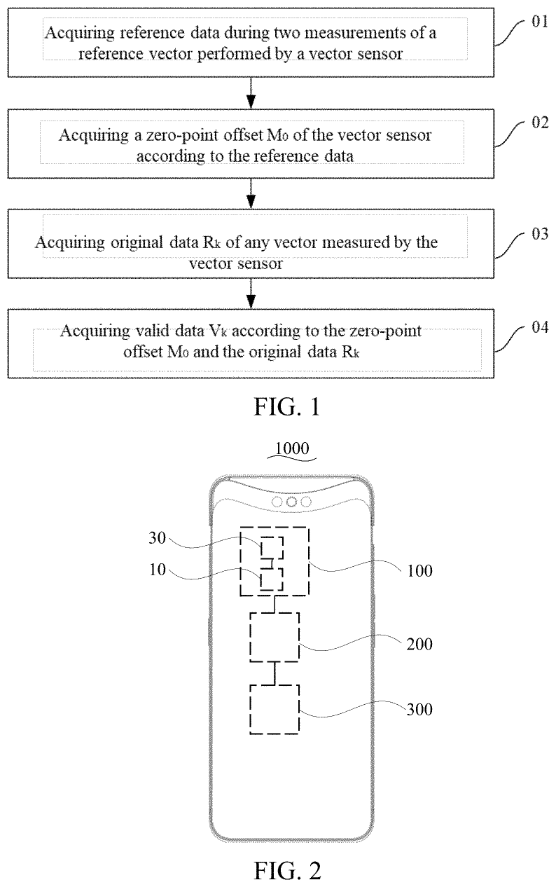

Referring to FIG. 1 to FIG. 3, an implementation of this application provides a zero-point calibration method for a vector sensor 200. The zero-point calibration method includes the following steps.

01: Acquiring reference data during two measurements of a reference vector performed by a vector sensor 200.

02: Acquiring a zero-point offset M₀ of the vector sensor 200 according to the reference data.

03: Acquiring original data Rₖ of any vector measured by the vector sensor.

04: Acquiring valid data Vₖ according to the zero-point offset M₀ and the original data Rₖ.

Referring to FIG. 2, an implementation of this application further provides an electronic device 1000. The electronic device 1000 includes the vector sensor 200 and a zero-point calibration device 100. The vector sensor 200 is configured to measure a vector. The zero-point calibration device 100 is configured to calibrate a zero-point point of the vector sensor 200. The zero-point calibration device 100 includes one or more processors 30, a memory 10, and one or more programs. The one or more programs are stored in the memory 10 and executable by the one or more processors 30. The processors 30 may be configured to perform the methods in 01, 02, 03, and 04. That is to say, the processor 30 may be configured to: acquire reference data during two measurements of a reference vector performed by a vector sensor 200; acquire a zero-point offset M₀ of the sensor according to the reference data; acquire original data Rₖ of any vector measured by the vector sensor 200; and acquire valid data Vₖ according to the zero-point offset M₀ and the original data Rₖ.

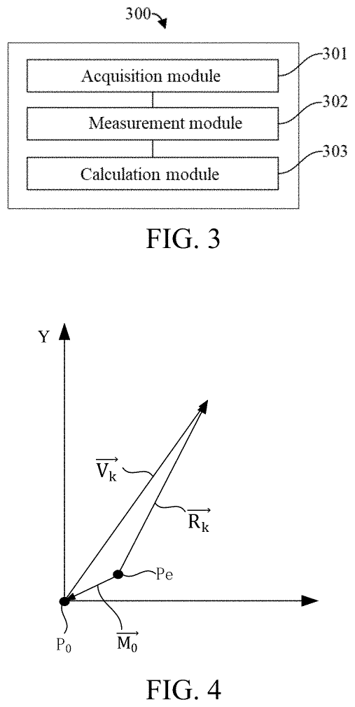

Referring to FIG. 2 and FIG. 3, an implementation of this application further provides a zero-point calibration apparatus 300. The zero-point calibration apparatus 300 is applicable to the electronic device 1000. That is to say, the electronic device 1000 further includes the zero-point calibration apparatus 300. The zero-point calibration apparatus 300 includes an acquisition module 301, a measurement module 302, and a calculation module 303. The acquisition module 301 may be configured to perform the methods in 01 and 02. The measurement module 302 may be configured to perform the method in 03. The calculation module 303 may be configured to perform the method in 04. That is to say, the acquisition module 301 may be configured to acquire the reference data during the two measurements of the reference vector performed by the vector sensor 200, and acquire the zero-point offset M₀ of the sensor according to the reference data. The measurement module 302 may be configured to acquire the original data Rₖ of any vector measured by the vector sensor 200. The calculation module 303 may be configured to acquire the valid data Vₖ according to the zero-point offset M₀ and the original data Rₖ.

Referring to FIG. 1 to FIG. 3, the vector sensor 200 may be a vector sensor 200 having two or more two axes, for example, a two-axis sensor, a three-axis sensor, a six-axis sensor, or a multi-axis sensor, which is not enumerated herein. Depending on a type of a to-be-measured vector, the vector sensor 200 may selectively be a geomagnetic sensor, a gravity acceleration sensor, an angular velocity sensor, an acceleration sensor, or the like, which is not enumerated herein. In some implementations, the vector sensor 200 may be a micro-electro-mechanical system (MEMS) sensor. The MEMS sensor may be configured to measure one or more types of vectors. For example, the MEMS sensor includes six axes, and can have functions of both a three-axis acceleration sensor and a three-axis geomagnetic sensor. The specific type of the MEMS sensor is not limited thereto, and is not enumerated herein.

The electronic device 1000 may be any electronic device 1000 having the vector sensor 200 installed thereon. For example, the electronic device 1000 may be a mobile phone, a tablet personal computer, a laptop computer, a personal digital assistant (PDA), a mobile Internet device (MID), a wearable device, an unmanned aerial vehicle, an unmanned vehicle, an unmanned ship, an intelligent robot, or the like, which is not enumerated herein.

Referring to FIG. 2, in an embodiment, the processor 30 and the vector sensor 200 are integrally fabricated and dispostured. In another embodiment, the processor 30 and the vector sensor 200 are independently fabricated and dispostured. The vector sensor 200 may transmit the measurement data to the processor 30. The processor 30 acquires the zero-point offset M₀ of the sensor according to data measured by the vector sensor 200, and transmits the zero-point offset M₀ to the vector sensor 200, so that the vector sensor 200 acquires the valid data Vₖ based on the zero-point offset M₀. Alternatively, the processor 30 side acquires the valid data Vₖ according to the zero-point offset M₀ and the original data Rₖ acquired by the vector sensor 200.

Generally, the zero-point offset M₀ exists between a theoretical zero-point position P₀ of the vector sensor 200 and a measurement zero-point position Pe adopted during the measurement by the vector sensor 200. Specifically, the vector sensor 200 can still acquire non-zero data when the to-be-measured vector is zero. A vector difference between the vector data acquired by the vector sensor 200 and zero-point is the zero-point offset M₀ of the vector sensor 200. If the vector sensor 200 adopts the theoretical zero-point position during measurement, the vector data acquired by the vector sensor 200 is zero when the to-be-measured vector is zero. That is to say, the vector data acquired by the vector sensor 200 can represent the real to-be-measured vector.

Since the zero-point offset M₀ is the vector difference between the theoretical zero-point position P₀ and the measurement zero-point position Pe, and the original data Rₖ acquired based on the measurement zero-point position Pe can reflect the zero-point position Pe, the theoretical zero-point position P₀ can be determined by using the zero-point offset M₀ based on the original data Rₖ acquired by the vector sensor 200 if the zero-point offset M₀ can be determined, thereby the accurate valid data Vₖ can be acquired. As the valid data Vₖ is acquired based on an actual zero-point position of the vector sensor 200, that is, acquired after a zero-point error is eliminated.

Specifically, referring to FIG. 2 and FIG. 4, the original data \vec{Rₖ} measured by the two-axis vector sensor 200 based on the measurement zero-point position Pe is used as an example. In a coordinate system of the two-axis vector sensor 200, P₀ is the theoretical zero-point position, Pe is the measurement zero-point position, \vec{M₀} is the vector difference between the theoretical zero-point position P₀ and the measurement zero-point position Pe, and \vec{Vₖ} is theoretical vector data that can be acquired based on the theoretical zero-point position P₀, which is a theoretical vector after the zero-point error of \vec{Rₖ} is eliminated. It can be learned that, P₀=Pe+\vec{M₀}, and \vec{Vₖ}=\vec{Rₖ}−\vec{M₀}. Therefore, the zero-point error of the original data \vec{Rₖ} can be eliminated to obtain the vector data \vec{Vₖ} if the zero-point offset M₀ can be determined, and the vector data \vec{Vₖ} is outputted as at the valid data to acquire an accurate measurement vector.

As such, the zero-point calibration method, the zero-point calibration device 100, the zero-point calibration apparatus 300 for the vector sensor 200, and the electronic device 1000 in the implementations of this application, the zero-point offset M₀ of the vector sensor 200 can be acquired according to the reference data during the two measurements of the reference vector, and the valid data Vₖ is acquired according to the original data Rₖ acquired by the vector sensor 200 and the zero-point offset M₀. The valid data Vₖ is vector data obtained after the zero-point error of the original data Rₖ is eliminated, which is more closely approximated to an actual value of the to-be-measured vector.

Following is a further description with reference to the accompanying drawings.

Refer back to FIG. 1. In the method in 01: Acquiring the reference data during the two measurements of the reference vector performed by the vector sensor 200, the reference vector may be a vector having a known modulus length. For example, the vector sensor is a geomagnetic sensor. In this case, the reference vector is a geomagnetic vector having a known magnitude.

In some implementations, during the two measurements of the reference vector by the vector sensor 200, postures of the vector sensor 200 are different. For the vector having the known modulus length, when the vector sensor 200 measures the vector at a different posture, acquired reference data is also different. Therefore, the zero-point offset M₀ can be acquired according to the different reference data.

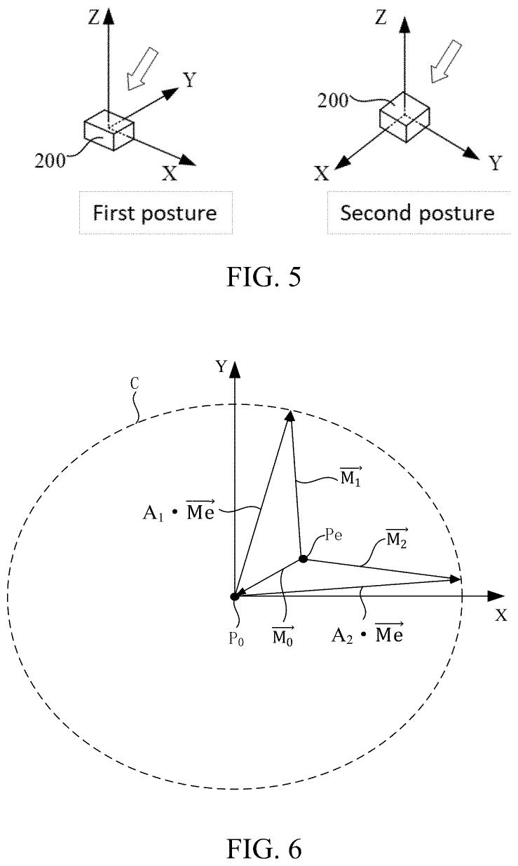

Referring to FIG. 5, specifically, different postures mean postures corresponding to different angles of the reference vector in a preset coordinate system relative to the vector sensor 200. For example, the vector sensor 200 is moved or rotated from a first posture to a second posture relative to a fixed reference vector. For example, the reference vector is an acceleration of gravity, and a direction of the acceleration of gravity is constant. In this case, the vector sensor 200 is moved or rotated relative to the direction of the acceleration of gravity to change the posture. For another example, the vector sensor 200 is not moved or rotated, but the reference vector is moved or rotated relative to the vector sensor 200. For example, the reference vector is an electromagnetic field vector, the vector sensor 200 is placed in a horizontal plane and kept still, and an electromagnetic field source is moved or rotated relative to the vector sensor 200. In this case, an angle of the electromagnetic field vector is changed relative to a coordinate axis of the vector sensor 200. Therefore, it is also considered that the vector sensor 200 is changed relative to the posture of the reference vector. For another example, at least one of the vector sensor 200 or the reference vector is moved or rotated relative to the other. For example, the vector sensor 200 is fixed, and the reference vector is movable, or the vector sensor 200 is movable, and the reference vector is fixed, or the vector sensor 200 and the reference vector are both movable. In all of the above cases, it is considered that the posture of the vector sensor 200 is changed relative to the reference vector.

In some implementations, the reference data includes a known reference vector value |Me|, an angular displacement vector θ from the posture of the vector sensor 200 during a first measurement to the posture during a second measurement, first measurement data M₁ acquired by the vector sensor 200 during the first measurement of the reference vector, and second measurement data M₂ acquired by the vector sensor 200 during the second measurement of the reference vector.

The reference vector value |Me| is a value of a reference vector Me, that is, a magnitude of the reference vector Me. The angular displacement vector θ may be measured by using an angular displacement sensor. Specifically, when a time interval between the first measurement and the second measurement by the vector sensor 200 is relatively small, an angular rotation vector θ of the angular displacement sensor during the second measurement by the vector sensor 200 may be used as the angular displacement vector θ from the posture of the vector sensor 200 during the first measurement to the posture during the second measurement.

Referring to FIG. 6, for example, a two-axis vector sensor acquires first measurement data \vec{M₁} and second measurement data \vec{M₂} at different postures relative to the reference vector \vec{Me}. Since the reference vector value |Me| of the reference vector \vec{Me} is constant, the vector data measured based on the theoretical zero-point position P₀ is a vector pointing to a circumference of a circle C from the theoretical zero-point position P₀. The circle C is a circle having P₀ as a center and |Me| as a radius. That is to say, a theoretical value of the first measurement data \vec{M₁} with the zero-point error eliminated is A₁·\vec{Me}, and a theoretical value of the second measurement data \vec{M₂} with the zero-point error eliminated is A₂·\vec{Me}, where A₁ is an external parameter matrix corresponding to the coordinate system of the vector sensor 200 at the first posture, A₂ is an external parameter matrix corresponding to the coordinate system of the vector sensor 200 at the second posture, and A₁·\vec{Me} and A₂·\vec{Me} illustrate an posture changing process of the vector sensor 200 relative to the reference vector.

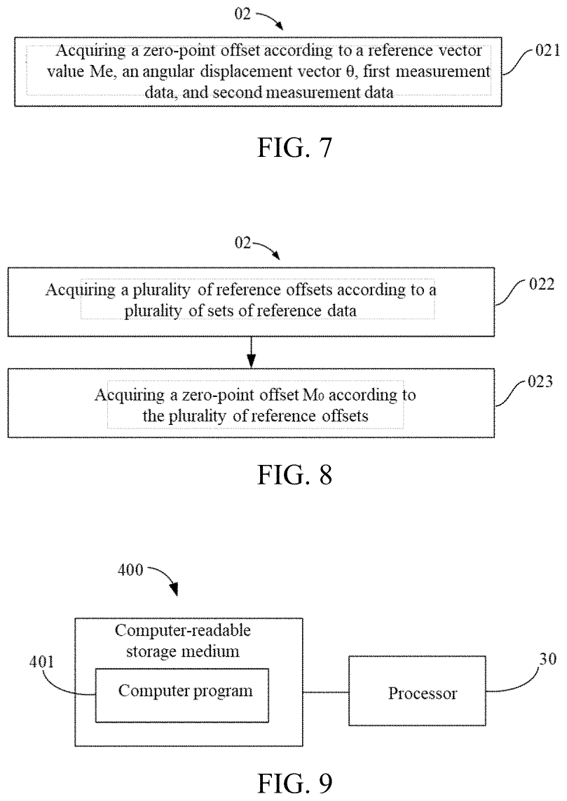

Referring to FIG. 7, further, in some implementations, the method in 02 of acquiring a zero-point offset M₀ of the sensor according to the reference data includes the following steps:

021: Acquiring the zero-point offset M₀ according to the reference vector value Me, the angular displacement vector θ, the first measurement data M₁, and the second measurement data M₂.

Referring to FIG. 2, in some implementations, the processor 30 may be further configured to perform the method in 021. That is to say, the processor 30 may be further configured to acquire the zero-point offset M₀ according to the reference vector value Me, the angular displacement vector θ, the first measurement data M₁, and the second measurement data M₂.

Referring to FIG. 3, in some implementations, the acquisition module 301 may be further configured to perform the method in 021. That is to say, the acquisition module 301 may be further configured to acquire the zero-point offset M₀ according to the reference vector value Me, the angular displacement vector θ, the first measurement data M₁, and the second measurement data M₂.

Specifically, referring to FIG. 6, A₁·\vec{Me} and A₂·\vec{Me} have the following relationship:

A₁·\vec{Me}=\vec{M₁}−\vec{M₀}; Formula I:

A₂·\vec{Me}=\vec{M₂}−\vec{M₀}. Formula II:

Formula III is obtained by using outer products of both sides of each of the equations of Formula I and Formula II.

|Me|²·sin \vec{θ}=(\vec{M₁}−\vec{M₂})×\vec{M₀}−\vec{M₁}×\vec{M₂}. Formula III:

In Formula III, |Me| is a modulus length (which is a constant) of the known reference vector \vec{Me}, \vec{θ} is the angular displacement vector within the time interval between the two measurements, and the first measurement data \vec{M₁} and the second measurement data \vec{M₂} are both measured by the vector sensor 200. Therefore, \vec{M₀} in Formula III is the unique unknown quantity. The acquired known quantities may be substituted into Formula III to obtain the zero-point offset \vec{M₀}.

Referring to FIG. 1 and FIG. 5, after the zero-point offset \vec{M₀} is acquired, during measurement of any vector by the vector sensor 200 at any postures, the valid data \vec{Vₖ} with the zero-point error eliminated may be acquired according to original data \vec{Rₖ} acquired by the vector sensor 200 by measuring any vector and the zero-point offset \vec{M₀}, so as to acquire the vector data obtained based on the theoretical zero-point position P₀ of the sensor, that is, the valid data \vec{Vₖ}, thereby realizing the zero-point calibration of the vector sensor 200.

Likewise, when the vector sensor 200 is a vector sensor 200 having more than two axes, the zero-point offset M₀ of the vector sensor 200 can still be acquired by means of the zero-point calibration method in the implementations of this application, so as to acquire the valid data Vₖ with the zero-point error eliminated according to the zero-point offset M₀ and the original data Rₖ measured by the vector sensor 200.

Referring to FIG. 8, in some implementations, Method 02 of acquiring the zero-point offset M₀ of the sensor according to the reference data further includes the following steps:

022: Acquiring a plurality of reference offsets according to a plurality of sets of reference data.

023: Acquiring the zero-point offset M₀ according to the plurality of reference offsets.

Referring to FIG. 2, in some implementations, the processor 30 may be further configured to perform the methods in 022 and 023. That is to say, the processor 30 may be further configured to acquire the plurality of reference offsets according to the plurality of sets of reference data, and acquire the zero-point offset M₀ according to the plurality of reference offsets.

Referring to FIG. 3, in some implementations, the acquisition module 301 may be further configured to perform the methods in 022 and 023. That is to say, the acquisition module 301 may be further configured to acquire the plurality of reference offsets according to the plurality of sets of reference data, and acquire the zero-point offset M₀ according to the plurality of reference offsets.

Specifically, in some implementations, in order to acquire an accurate zero-point offset M₀, a plurality of sets of measurements may be performed to acquire a plurality of reference offsets, and the zero-point offset M₀ is acquired according to the plurality of reference offsets. Referring to FIG. 8, reference data of each set of measurements includes a known reference vector value |Me|, an angular displacement vector θ from an posture of the vector sensor 200 during a first measurement to an posture during a second measurement in the set of measurements, first measurement data M₁ acquired by the vector sensor 200 during the first measurement of the reference vector in the set of measurements, and second measurement data M₂ acquired by the vector sensor 200 during the second measurement of the reference vector in the set of measurements. Referring to Formula III, the reference offset N may be determined according to the following formula: |Me|²·sin \vec{θ}=(\vec{M₁}−\vec{M₂})×\vec{N₁}−\vec{M₁}×\vec{M₂}, where i is a natural number greater than 0, and the reference offset \vec{N₁} is a reference offset acquired by an i^{th} set of measurements.

In an embodiment, an average value of the plurality of reference offsets \vec{N₁} may be used as the zero-point offset \vec{M₀}. For example, the vector sensor 200 is a two-axis sensor. The vector sensor 200 performs 3 sets of measurements on the reference vector and then acquires a reference offset \vec{N₁}, a reference offset \vec{N₂}, and a reference offset \vec{N₃}. A component of the zero-point offset \vec{M₀} on a Y axis of the vector sensor 200 is expressed as \vec{M_{0,y}}=(\vec{N_{1,y}}+\vec{N_{2,y}}+\vec{N_{3,y}})/3, where \vec{N_{1,y}}, \vec{N_{2,y}}, and \vec{N_{3,y}} are respectively components of the reference offset \vec{N₁}, the reference offset \vec{N₂}, and the reference offset \vec{N₃} on the Y axis of the vector sensor 200. A component of the zero-point offset \vec{M₀} on an X axis of the vector sensor 200 is expressed as \vec{M_{0,x}}=(\vec{N_{1,x}}+\vec{N_{2,x}}+\vec{N_{3,x}})/3, where \vec{N_{1,x}}, \vec{N_{2,x}}, and \vec{N_{3,x}} are respectively components of the reference offset \vec{N₁}, the reference offset \vec{N₂}, and the reference offset \vec{N₃} on the Y axis of the vector sensor 200. The zero-point offset \vec{M₀}=\vec{M_{0,x}}+\vec{M_{0,y}}.

In another embodiment, statistics, such as a median, a weighted average, a variance, and a standard deviation of the plurality of reference offsets \vec{N₁} may be used as the zero-point offset \vec{M₀}. The statistics are not enumerated herein.

In some implementations, the vector sensor 200 continuously acquires the reference data, and acquires the reference offset according to the reference data, and continuously updates the current zero-point offset according to the newly acquired reference offset. During adjacent two measurements, postures of the vector sensor 200 relative to the reference vector are different.

For example, the vector sensor 200 acquires first measurement data M₁, second measurement data M₂, and an angular displacement vector θ_{1, 2} after the first measurement and the second measurement. The angular displacement vector θ_{1, 2} is the angular displacement vector from the posture of the vector sensor 200 during the first measurement and the posture during the second measurement. A vector value |Me| of the reference vector Me is known. According to M₁, M₂, θ_{1, 2}, and |Me|, the reference offset N₁ can be acquired. The reference offset N₁ is used as the current zero-point offset M₀. Then, the vector sensor 200 acquires third measurement data M₃ and an angular displacement vector θ₂₋₃ after a third measurement. According to M₂, M₃, θ_{2, 3}, and |Me|, the reference offset N₂ can be acquired. An average of N₁ and N₂ is used as the current zero-point offset M₀. Similarly, the vector sensor 200 acquires fourth measurement data M₄ and an angular displacement vector θ_{3, 4} after a fourth measurement. According to M₃, M₄, θ_{3, 4}, and |Me|, a reference offset N₃ can be acquired. An average of N₁, N₂, and N₃ is used as the current zero-point offset M₀. Similarly, the vector sensor 200 continuously acquires the measurement data. When the vector sensor 200 acquires k^{th} measurement data Mₖ and an angular displacement vector θ_{k-1, k} after a k^{th} measurement, according to Mₖ₋₁, Mₖ, θ_{k-1, k}, and |Me|, a reference offset Nₖ₋₁ can be acquired. An average of N₁, N₂, N₃, . . . , Nₖ₋₂, Nₖ₋₁ is used as the current zero-point offset M₀. As such, the vector sensor 200 may continuously acquire the measurement data, and update the current zero-point offset M₀ according to the continuously acquired measurement data, so as to ensure that the current zero-point offset M₀ is accurate.

Further, in some implementations, the vector sensor 200 continuously acquires the reference data, and acquires the reference offset according to the reference data, and continuously updates the current zero-point offset according to the newly acquired reference offset, and acquires the valid data corresponding to the reference data according to the current zero-point offset and the reference data.

For example, based on the above, after acquiring the reference offset N₁ and the current zero-point offset M₀ according to M₁, M₂, θ_{1, 2}, and |Me|, the vector sensor 200 acquires the valid data V₂ corresponding to M₂ according to M₂ and M₀, where V₂=M₂−M₀. That is to say, the valid data V₂ is vector data after a zero-point error of the second measurement data M₂ is eliminated. Then, the vector sensor 200 performs the third measurement to acquire M₃ and θ_{2, 3}, acquires the reference offset N₂ according to M₂, M₃, θ_{2, 3}, and |Me|, and updates the current zero-point offset M₀ according to N₁ and N₂. After the current zero-point offset M₀ is updated, the valid data V₃ corresponding to M₃ can be acquired according to M₃ and M₀. Similarly, the vector sensor 200 may continuously acquire the reference data to update the current zero-point offset M₀, and may acquire the valid data Vₖ corresponding to the measurement data Mₖ according to the k^{th} measurement data Mₖ and the updated zero-point offset M₀. In this way, the vector sensor 200 can normally acquire the zero-point offset M₀, that is, the normally outputs the valid data.

In another embodiment, after acquiring the reference offset N₁ and the current zero-point offset M₀ according to M₁, M₂, θ_{1, 2}, and |Me|, after a next measurement, that is, the third measurement, the vector sensor 200 acquires the valid data V₃ corresponding to M₃ according to the zero-point offset M₀ obtained according to the data of the first measurement and the second measurement and the third measurement data M₃, then acquires the reference offset N₂ according to M₂, M₃, θ_{2, 3}, and |Me|, and updates the current zero-point offset M₀ according to N₁ and N₂, so as to use the updated zero-point offset M₀ after the third measurement for acquiring the valid data V₄ during the fourth measurement. Similarly, the vector sensor 200 may acquire valid data Vₖ₊₁ corresponding to measurement data Mₖ₊₁ according to the updated zero-point offset M₀ after the k^{th} measurement and (k+1)^{th} measurement data Mₖ₊₁. That is to say, before the sensor acquires the k+1 measurement data Mₖ₊₁, the zero-point offset M₀ for acquiring the valid data Vₖ₊₁ has been updated. Therefore, the valid data Vₖ₊₁ can be immediately outputted according to Mₖ₊₁ and M₀ acquired by the k^{th} measurement when the sensor acquires k+1 measurement data Mₖ₊₁.

Referring to FIG. 9, an implementation of this application further provides a non-volatile computer-readable storage medium 400 including a computer program 401. When the computer program 401 is executed by one or more processors 30, the one or more processors 30 are caused to perform the calibration method described in any of the above implementations. The non-volatile computer-readable storage medium 400 may be dispostured in the electronic device 1000, or may be dispostured in a cloud server or other apparatuses. In this case, the electronic device 1000 can communicate with the cloud server or the other apparatuses to acquire the corresponding computer program 401.

Referring to FIG. 2, for example, when the computer program 401 is executed by one or more processors 30, the one or more processors 30 are caused to perform the methods in 01, 02, 03, 04, 021, 022, and 023. For example, the following application calibration method is performed.

01: Acquiring reference data during two measurements of a reference vector performed by a vector sensor 200.

02: Acquiring a zero-point offset M₀ of the sensor according to the reference data.

03: Acquiring original data Rₖ of any vector measured by the vector sensor.

04: Acquiring valid data Vₖ according to the zero-point offset M₀ and the original data Rₖ.

For another example, when the computer program 401 is executed by one or more processors 30, the one or more processors 30 are caused to perform the following calibration method.

01: Acquiring reference data during two measurements of a reference vector performed by a vector sensor 200.

021: Acquiring a zero-point offset M₀ according to a reference vector value Me, an angular displacement vector θ, first measurement data M₁, and second measurement data M₂.

022: acquiring a plurality of reference offsets according to a plurality of sets of reference data.

023: Acquiring the zero-point offset M₀ according to the plurality of reference offsets.

03: Acquiring original data Rₖ of any vector measured by the vector sensor.

04: Acquiring valid data Vₖ according to the zero-point offset M₀ and the original data Rₖ.

In the description of this specification, description of reference terms such as “some implementations”, “in an example” or “exemplary”, means including specific features, structures, materials, or features described in the implementation or example in at least one implementation or example of this application. In this specification, schematic descriptions of the foregoing terms are not necessarily with respect to the same implementation or example. In addition, the described specific characteristics, structures, materials, or features may be combined in a proper manner in any one or more implementations or examples. In addition, a person skilled in the art may integrate or combine different embodiments or examples described in the specification and features of the different embodiments or examples as long as they are not contradictory to each other.

Any process or method in the flowcharts or described herein in another manner may be understood as indicating a module, a segment, or a part including code of one or more executable instructions for implementing a particular logical function or process step. In addition, the scope of preferred embodiments of this application includes other implementations which do not follow the order shown or discussed, including performing, according to involved functions, the functions basically simultaneously or in a reverse order, which is to be understood by a person skilled in the art to which the embodiments of this application belong.

Although the implementations of this application are shown and described above, it may be understood that the foregoing implementations are exemplary, and cannot be understood as a limitation to this application. A person of ordinary skill in the art may make changes, modifications, replacements, and variations to the foregoing embodiments without departing from the scope of this application.

What is claimed is:

1. A vector sensor zero-point calibration method, comprising:
acquiring reference data during two measurements of a reference vector performed by a vector sensor, wherein the reference vector is a vector having a known modulus length;
acquiring a zero-point offset M₀ of the vector sensor according to the reference data, wherein the zero-point offset M₀ is vector difference between a theoretical zero-point position P₀, and a measurement zero-point position Pe of the vector sense;
acquiring original data Rₖ of any vector measured by the vector sensor, wherein the original data Rₖ is vector data acquired based on the measurement zero-point position Pe; and
acquiring valid data Vₖ according to the zero-point offset M₀ and the original data Rₖ, thereby realizing the zero-point calibration of the vector sensor, wherein the valid data Vₖ is based on the theoretical zero-point position P₀, and the valid data Vₖ is vector data obtained after the zero-point error of the original data Rₖ is eliminated;
wherein during the two measurements of the reference vector by the vector sensor, poses of the vector sensor are different;
the reference data include a known reference vector value Me, an angular displacement vector θ from the pose of the vector sensor during a first measurement of the pose during a second measurement, first measurement data M₁ acquired by the vector sensor during the first measurement of the reference vector, and second measurement data M₂ acquired by the vector sensor during the second measurement of the reference vector; and
the acquiring the zero-point offset M₀ of the vector sensor according to the reference data comprises: acquiring the zero-point offset M₀ according to the reference vector value Me, the angular displacement vector θ, the first measurement data M₁, and the second measurement data M₂.

2. (canceled)

3. (canceled)

4. The zero-point calibration method according to claim 1, wherein the reference data comprises a plurality of sets of reference data, and the acquiring a zero-point offset M₀ of the vector sensor according to the reference data comprises:
acquiring a plurality of reference offsets according to the plurality of sets of reference data; and
acquiring the zero-point offset M₀ according to the plurality of reference offsets.

5. A zero-point calibration device, comprising one or more processors, a memory, and one or more programs stored in the memory and executable by the one or more processors, wherein the processors are configured to:
acquire reference data during two measurements of a reference vector performed by a vector sensor, wherein the reference vector is a vector having a known modulus length;
acquire a zero-point offset M₀ of the vector sensor according to the reference data, wherein the zero-point offset M₀ is vector difference between a theoretical zero-point position P₀ and a measurement zero-point position Pe of the vector sensor;
acquire original data Rₖ of any vector measured by the vector sensor, wherein the original data Rₖ is vector data acquired based on the measurement zero-point position Pe; and
acquire valid data Vₖ according to the zero-point offset M₀ and the original data Rₖ, thereby realizing the zero-point calibration of the vector sensor, wherein the valid data Vₖ is based on the theoretical zero-point position P₀, and the valid data Vₖ is vector data obtained after the zero-point error of the original data Rₖ is eliminated;
wherein during the two measurements of the reference vector by the vector sensor, poses of the vector sensor are different;
the reference data include a known reference vector value Me, an angular displacement vector θ from the pose of the vector sensor during a first measurement of the pose during a second measurement, first measurement data M₁ acquired by the vector sensor during the first measurement of the reference vector, and second measurement data M₂ acquired by the vector sensor during the second measurement of the reference vector, and
the processors are further configured to acquire the zero-point offset M₀ according to the reference vector value Me, the angular displacement vector θ, the first measurement data M₁, and the second measurement data M₂.

6. (canceled)

7. The zero-point calibration device according to claim 5, wherein the processors are further configured to:
acquire a plurality of reference offsets according to the plurality of sets of reference data; and
acquire the zero-point offset M₀ according to the plurality of reference offsets.

8. An electronic device, comprising:
a vector sensor, configured to measure a vector; and
the zero-point calibration device according to claim 5.

9. (canceled)

10. The electronic device according to claim 8, wherein the processors are further configured to:
acquire a plurality of reference offsets according to the plurality of sets of reference data; and
acquire the zero-point offset M₀ according to the plurality of reference offsets.

11. A non-transitory computer-readable storage medium, storing a computer program, wherein when the computer program is executed by one or more processors, the zero-point calibration method according to claim 1.

12. (canceled)

13. (canceled)

14. The non-transitory computer-readable storage medium according to claim 11, wherein the reference data comprises a plurality of sets of reference data, and the acquiring a zero-point offset M₀ of the vector sensor according to the reference data comprises:
acquiring a plurality of reference offsets according to the plurality of sets of reference data; and
acquiring the zero-point offset M₀ according to the plurality of reference offsets.

15. A mobile internet device, comprising:
a vector sensor, configured to measure a vector; and
the zero-point calibration device according to claim 5.

16. The mobile internet device according to claim 15, wherein the processors are further configured to:
acquire a plurality of reference offsets according to the plurality of sets of reference data; and
acquire the zero-point offset M₀ according to the plurality of reference offsets.

17. A wearable device, comprising:
a vector sensor, configured to measure a vector; and
the zero-point calibration device according to claim 5.

18. The wearable device according to claim 17, wherein the processors are further configured to:
acquire a plurality of reference offsets according to the plurality of sets of reference data; and
acquire the zero-point offset M₀ according to the plurality of reference offsets.

19. An unmanned aerial vehicle, comprising:
a vector sensor, configured to measure a vector; and
the zero-point calibration device according to claim 5.

20. The unmanned aerial vehicle according to claim 19, wherein the processors are further configured to:
acquire a plurality of reference offsets according to the plurality of sets of reference data; and
acquire the zero-point offset M₀ according to the plurality of reference offsets.

21. An unmanned vehicle, comprising:
a vector sensor, configured to measure a vector; and
the zero-point calibration device according to claim 5.

22. The unmanned vehicle according to claim 21, wherein the processors are further configured to:
acquire a plurality of reference offsets according to the plurality of sets of reference data; and
acquire the zero-point offset M₀ according to the plurality of reference offsets.

23. An unmanned ship, comprising:
a vector sensor, configured to measure a vector; and
the zero-point calibration device according to claim 5.

24. The unmanned ship according to claim 23, wherein the processors are further configured to:
acquire a plurality of reference offsets according to the plurality of sets of reference data; and
acquire the zero-point offset M₀ according to the plurality of reference offsets.

25. An intelligent robot, comprising:
a vector sensor, configured to measure a vector; and
the zero-point calibration device according to claim 5.

26. The intelligent robot according to claim 25, wherein the processors are further configured to:
acquire a plurality of reference offsets according to the plurality of sets of reference data; and
acquire the zero-point offset M₀ according to the plurality of reference offsets.
